(19) United States
(12) Patent Application Publication
(10) Pub. No.: US 2004/0085096 A1
(43) Pub. Date: May 6, 2004

(54) Efficient digital method of and system for determining the instantaneous phase and amplitude of a vibratory accelerometer and other sensors

(76) Inventors: Paul A. Ward, Roslindale, MA (US); David J. McGorty, Holliston, MA (US); Lane G. Brooks, Somerville, MA (US)

Correspondence Address: McDermott, Will & Emery, 28 State Street, Boston, MA, 02109-1775, US

(21) Appl. No.: 10/691,866

(22) Filed: Oct. 23, 2003

Related U.S. Application Data
(63) Continuation of application No. 09/837,827, filed on Apr. 18, 2001, now abandoned.

(51) Int. Cl. H03D 3/00

(52) U.S. Cl. 327/2

(57) ABSTRACT

A system for determining the instantaneous amplitude (a) and phase (φ) of an analog sinusoid includes a sensor which produces the analog sinusoid output in response to the measurement of a parameter, an analog-to-digital converter which receives the analog sinusoid from the sensor and converts the analog sinusoid to a digital sinusoid, a delay device which receives the digital sinusoid and produces an in-phase signal (I) associated with the digital sinusoid, a transformer which receives the digital sinusoid and produces a quadrature signal (Q) associated with the digital sinusoid by introducing a phase shift plus a delay to the digital sinusoid, an amplitude computation device which receives the in-phase (I) and quadrature (Q) signals and computes the instantaneous amplitude (a) of the digital sinusoid by processing the in-phase (I) and quadrature (Q) signals according to the equation a=\sqrt{(Q²+I²)} and a phase computation device which receives the in-phase (I) and quadrature (Q) signals and computes the instantaneous phase (φ) of the digital sinusoid by processing the in-phase (I) and quadrature (Q) signals according to the equation φ=tan⁻¹(Q/I).

### FIELD OF THE INVENTION

The present invention relates generally to a method of and system for determining the instantaneous phase and amplitude of a sinusoid and more particularly to a method of and system for obtaining the instantaneous phase and amplitude of the sinusoidal output from a vibratory accelerometer and other sensors having a sinusoidal output.

### BACKGROUND OF THE INVENTION

Many sensors produce a nominally sinusoidal output signal where the sinusoid amplitude or phase, or both, must be instantaneously determined in order to precisely estimate the input variable. For example, in the case of a vibratory accelerometer, there is generally a pair of tuning forks consisting of vibrating beams. With an acceleration along the beam axis, one tuning-fork structure is in tension, increasing its frequency, while the other tuning-fork structure is in compression, reducing its frequency. The output signal associated with each tuning-fork can be considered a general modulated sinusoid having the form:

x(t)=a(t)cos(ωₒt+θ(t))=a(t)cos φ(t) Eq. (1)

where

a(t) is the instantaneous amplitude; and

φ(t) is the generalized instantaneous phase.

The generalized instantaneous phase φ(t) includes frequency information, as shown in the equation for the instantaneous (radian) frequency:

$$ω ( t ) = \frac{ⅆ}{ⅆ t} ϕ ( t ) = {ω}_{o} + \frac{ⅆ}{ⅆ t} θ ( t ) \qquad Eq . ( 2 )$$

In other words, ωₒ is the time-average frequency, and the frequency modulation is given by the time derivative of θ(t).

In the example of the accelerometer, amplitude modulation may result from uncompensated power flow out of the respective oscillator, which can result from environmental effects or acceleration. Frequency modulation may result from a variation in the oscillator beam stiffness resulting from inertial acceleration. In order to control and compensate for the amplitude modulation, the amplitude of the sinusoid output signal must be measured. Once measured, the environmental and acceleration effects on the output of the accelerometer can be corrected. Furthermore, because the frequency output is related to the acceleration, the phase of the output signal must be measured in order to determine velocity. It is important to measure amplitude and frequency modulation at a high sample rate because the amplitude and frequency of the sinusoid may include large and rapid variations in the presence of large and rapid accelerations.

There are several conventional methods for measuring amplitude, including methods that require a tracking reference oscillator. However, the conventional methods suffer from excessive rectification of noise and spurious signals, errors in tracking phase, large environmental sensitivities and high ripple level. Likewise, prior art methods for measuring phase, including counting sinusoidal zero crossings suffer from large quantization error, in that the phase measurement over any finite time interval is in error by up to ½ cycle with respect to true phase. This quantization error will manifest itself as noise on the measured phase, and errors in the inferred velocity in the case of an accelerometer. The phase quantization error can be reduced by interpolating within a sinusoid cycle by using a phase-lock loop and with analog integration. The phase-lock loop technique suffers because it introduces linear distortion in the phase modulation, which are errors that vary depending on the frequency of the phase variations. Analog integration techniques are subject to various errors associated with analog components.

### SUMMARY OF THE INVENTION

The present invention includes a method of and system for measuring the instantaneous amplitude and phase of a sinusoid output of a vibratory accelerometer and other sensors. The system first digitizes the sinusoid and then passes the digitized sinusoid through a band pass filter in order to attenuate out of band noise such as harmonics in the sinusoid and remove DC. The digitized sinusoid is then delayed to produce the in-phase signal associated with the sinusoid. A phase shift is introduced to the sinusoid in order to produce the quadrature signal associated with the sinusoid. The in-phase and quadrature signals are then processed to determine the instantaneous amplitude and phase of the sinusoid. Note that the delay introduced in the in-phase signal compensates for the fixed time delay in the quadrature signal.

According to a first aspect of the invention, a method of determining the instantaneous amplitude (a) and phase (φ) of a sinusoid includes:

A. digitizing the sinusoid to form a first signal which is the in-phase component (I) of the sinusoid;

B. introducing a phase shift into the digitized sinusoid to produce the quadrature component (Q) of the sinusoid;

C. processing the in-phase and quadrature components to compute the instantaneous phase (φ) of the sinusoid; and

D. processing the in-phase and quadrature components to compute the instantaneous amplitude (a) of the sinusoid.

The method may further include filtering the sinusoid before step B. Step B may further include introducing a predetermined delay into the quadrature component (Q). The method may further include introducing the predetermined delay into the in-phase component (I) before step C. Step C may further include processing the in-phase and quadrature signals according to the equation φ=tan⁻¹(Q/I). Step D may include processing the in-phase and quadrature signals according to the following equation a=\sqrt{(Q²+I²)}. The filtering step may include attenuating out-of-band noise in the sinusoid. The sinusoid may be an output of a vibratory sensor, such as an accelerometer.

According to another aspect of the invention, a system for determining the instantaneous phase and amplitude of an analog sinusoid includes (i) a sensor which produces the analog sinusoid output in response to the measurement of a parameter, (ii) an analog-to-digital converter which receives the analog sinusoid from the sensor and converts the analog sinusoid to a digital sinusoid which represents the in-phase component (I) of the sinusoid, (iii) a phase shift device which receives the digital sinusoid and produces the quadrature component (Q) of the digital sinusoid by introducing a phase shift to the digital sinusoid, (iv) an amplitude computation device which receives the in-phase (I) and quadrature (Q) components and computes the instantaneous amplitude (a) of the digital sinusoid and (v) a phase computation device which receives the in-phase (I) and quadrature (Q) components and computes the instantaneous phase (φ) of the digital sinusoid.

The system may further include a filter device which receives the digital sinusoid from the analog-to-digital converter and removes out-of-band noise in the digital sinusoid before passing the digital sinusoid to the phase shift device. The phase shift device may produce the quadrature signal (Q) by introducing a −90 degree phase shift into the digital sinusoid. The phase shift device may further introduce a predetermined delay into the quadrature component (Q). The system may further include a delay device which introduces the predetermined delay into the in-phase component (I). The phase shift device may include a Hilbert transformer approximation device. The amplitude computation device may compute the instantaneous amplitude (a) of the digital sinusoid by processing the in-phase (I) and quadrature (Q) signals according to the equation a=\sqrt{(Q²+I²)}. The phase computation device may compute the instantaneous phase (φ) of the digital sinusoid by processing the in-phase (I) and quadrature (Q) signals according to the equation φ=tan⁻¹(Q/I). The amplitude computation device may compute the instantaneous amplitude (a) of the digital sinusoid by processing the in-phase (I) and quadrature (Q) signals according to the CORDIC algorithm. The phase computation device may compute the instantaneous phase (φ) of the digital sinusoid by processing the in-phase (I) and quadrature (Q) signals according to the CORDIC algorithm. The sensor may include one of an accelerometer, a gyroscope, a microphone, a vibration sensor and a chemical sensor.

According to another aspect of the invention, a system for determining the instantaneous amplitude (a) and phase (φ) of an analog sinusoid includes (i) a sensor which produces the analog sinusoid output in response to the measurement of a parameter (ii) an analog-to-digital converter which receives the analog sinusoid from the sensor and converts the analog sinusoid to a digital sinusoid to form the in-phase component (I) of the sinusoid, (iii) a Hilbert transformer approximation device which receives the digital sinusoid and produces the quadrature component (Q) of the digital sinusoid by introducing a phase shift to the digital sinusoid, (iv) an amplitude computation device which receives the in-phase (i) and quadrature (Q) components and computes the instantaneous amplitude (a) of the digital sinusoid by processing the in-phase (I) and quadrature (Q) components according to the equation a=\sqrt{(Q²+I²)}; and (v) a phase computation device which receives the in-phase (I) and quadrature (Q) components and computes the instantaneous phase (φ) of the digital sinusoid by processing the in-phase (I) and quadrature (Q) components according to the equation φ=tan⁻¹(Q/I).

The Hilbert transformer approximation device may further introduce a predetermined delay into the quadrature component (Q) and the system may include a delay device which introduces the predetermined delay into the in-phase component (I).

According to another aspect of the invention, a system for determining the instantaneous amplitude and phase of an analog sinusoid includes (i) a sensor which produces the analog sinusoid output in response to the measurement of a parameter, (ii) an analog-to-digital converter which receives the analog sinusoid from the sensor and converts the analog sinusoid to a digital sinusoid sinusoid to form the in-phase component (I) of the sinusoid, (iii) a Hilbert transformer approximation device which receives the digital sinusoid and produces the quadrature component (Q) of the digital sinusoid by introducing a phase shift to the digital sinusoid, (iv) an amplitude computation device which receives the in-phase (I) and quadrature (Q) components and computes the instantaneous amplitude (a) of the digital sinusoid by processing the in-phase (I) and quadrature (Q) components according to the CORDIC algorithm and (v) a phase computation device which receives the in-phase (I) and quadrature (Q) components and computes the instantaneous phase (φ) of the digital sinusoid by processing the in-phase (I) and quadrature (Q) components according to the CORDIC algorithm.

According to another aspect of the invention, a method of determining the amplitude (a) and phase (φ) of a sinusoid includes:

A. measuring a parameter with a sensor;

B. generating an analog sinusoid representative of the parameter;

C. digitizing the analog sinusoid to produce a digital sinusoid;

D. filtering the digital sinusoid to attenuate out-of-band noise in the digital sinusoid;

E. producing an in-phase signal (I) associated with the digital sinusoid;

F. introducing a phase shift into the digital sinusoid to produce a quadrature signal (Q) associated with the digital sinusoid;

G. processing the in-phase (I) and quadrature (Q) signals to compute the amplitude (a) of the digital sinusoid by applying the equation a=\sqrt{(Q²+I²)}; and

H. processing the in-phase (I) and quadrature (Q) signals to compute the phase (φ) of the digital sinusoid by applying the equation φ=tan⁻¹(Q/I).

Step F may include introducing a predetermined delay into the digital sinusoid. The method may include introducing the predetermined delay into the in-phase signal (I) prior to step G.

According to another aspect of the invention, a method of determining the amplitude (a) and phase (φ) of a sinusoid includes:

A. measuring a parameter of an object with a sensor;

B. generating an analog sinusoid representative of the parameter;

C. digitizing the analog sinusoid to produce a digital sinusoid;

D. filtering the digital sinusoid to attenuate out-of-band noise and other spurious artifacts in the digital sinusoid;

E. introducing a delay into the digital sinusoid to produce an in-phase signal (I) associated with the digital sinusoid;

F. performing a Hilbert transform approximation of the digital sinusoid to introduce a phase shift plus delay into the digital sinusoid, thereby producing a quadrature signal (Q) associated with the digital sinusoid;

G. processing the in-phase (I) and quadrature (Q) signals to compute the amplitude (a) of the digital sinusoid by applying the equation a=\sqrt{(Q²+I²)}; and

H. processing the in-phase (I) and quadrature (Q) signals to compute the phase (φ) of the digital sinusoid by applying the equation φ=tan⁻¹(Q/I).

According to yet another aspect of the invention, a method of determining the amplitude (a) and phase (φ) of a sinusoid includes:

A. measuring a parameter of an object with a sensor;

B. generating an analog sinusoid representative of the parameter;

C. digitizing the analog sinusoid to produce a digital sinusoid;

D. filtering the digital sinusoid to attenuate out-of-band noise in the digital sinusoid;

E. producing an in-phase signal (I) associated with the digital sinusoid;

F. introducing a phase shift into the digital sinusoid, thereby producing a quadrature signal (Q) associated with the digital sinusoid;

G. processing the in-phase (I) and quadrature (Q) signals to compute the amplitude (a) of the digital sinusoid according to the CORDIC algorithm; and

H. processing the in-phase (I) and quadrature (Q) signals to compute the phase (φ) of the digital sinusoid according to the CORDIC algorithm.

### BRIEF DESCRIPTION OF THE DRAWINGS

The foregoing and other objects of this invention, the various features thereof, as well as the invention itself may be more fully understood from the following description when read together with the accompanying drawings in which:

FIG. 1 is a schematic block diagram of the system for determining the instantaneous amplitude and phase of a sinusoid in accordance with the present invention;

FIG. 2 is a flow diagram of the method of determining the instantaneous amplitude and phase of a sinusoid in accordance with the present invention; and

FIG. 3 is a graph of a rotating digital vector in accordance with the present invention.

### DETAILED DESCRIPTION

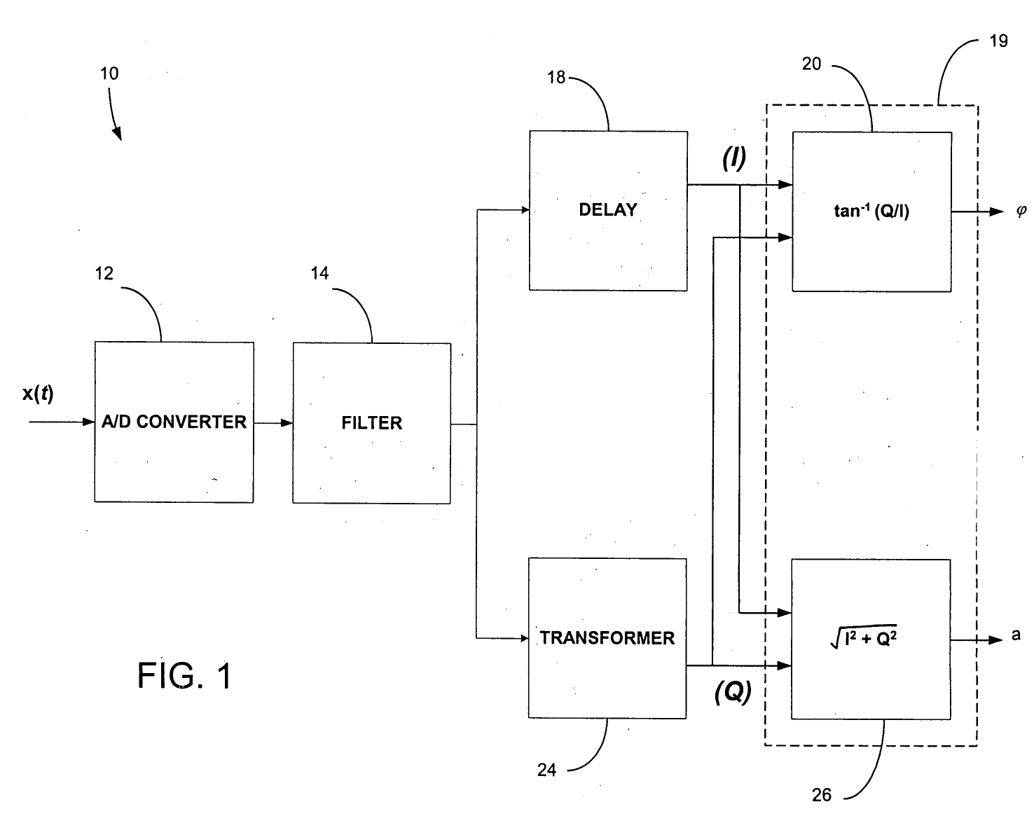

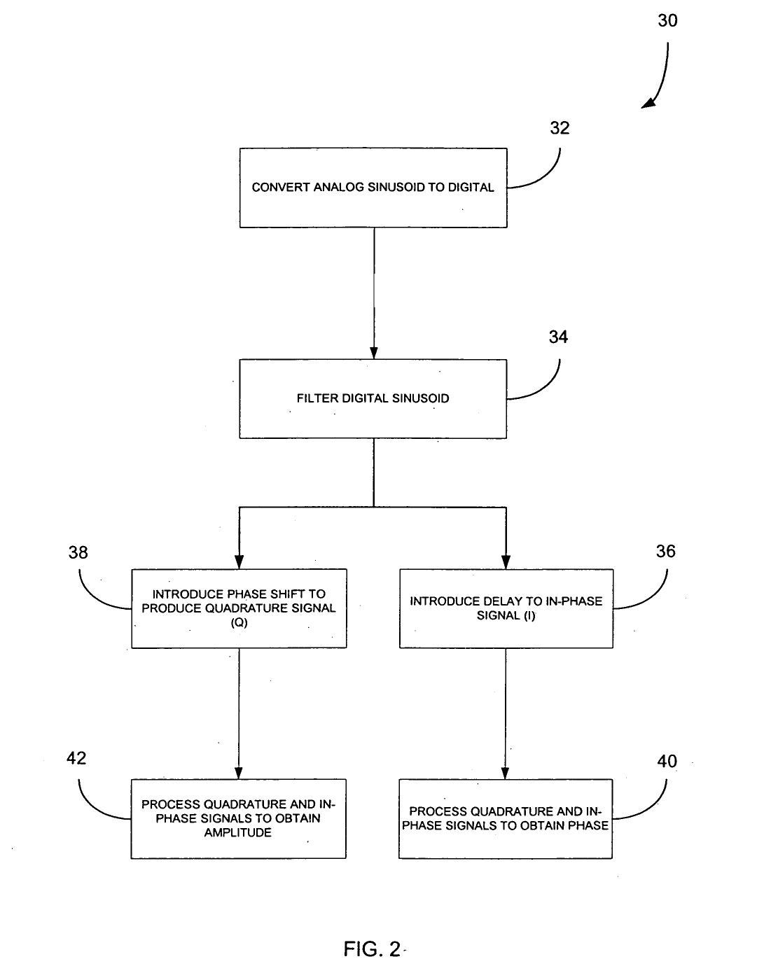

The present invention will now be described in detail with reference to FIGS. 1 and 2. As shown in FIG. 1, the system 10 includes an analog-to-digital converter 12, a filter 14, a delay device 18, a transformer 24 and a processor 19 including a phase processor 20, and an amplitude processor 26. FIG. 2 is a flow diagram of the method 30 performed by the system 10 to determine the instantaneous amplitude and phase of the input sinusoid. While, as described below, the preferred embodiment uses a well-known Hilbert transformation approximation technique to convert sampled values, other techniques known to those skilled in the art for introducing a phase shift to a sinusoid may be used as well.

As set forth above, the output of a sensor (not shown) is a sinusoid x(t)=a(t)cos φ(t). This analog signal is input to A/D converter 12 and preferably sampled at ten times the sinusoid frequency, step 32, resulting in a sampling rate of 10 samples per cycle. The digitized sinusoid x[n] is input to filter 14, step 34, which is preferably a digital band-pass filter, which is used to attenuate out-of-band noise such as harmonics and other spurious signals, particularly those close to the sinusoid frequency. Filter 14 may be a finite impulse-response type of filter.

The filtered, digitized signal x[n] is passed to transformer 24 where a phase shift is introduced, step 38. Transformner 24 is a digital filter that emulates the operation of an ideal Hilbert transformer over a specific frequency band, which has the following transfer function:

$$H ( j ω ) = \{ \begin{matrix}j , & ω < 0 \\ - j , & ω > 0\end{matrix} \qquad Eq . ( 3 )$$

Since, in practice, the ideal Hilbert transformner, as defined in Eq. 3, cannot be realized, the transformer 24 of the present invention produces an approximation of the ideal transform shown in Eq. 3. As a result of the approximation, transformer 24 introduces a −90 degree phase shift as well as a delay to the sinusoid x[n]. Therefore, the output of the Hilbert transformer, y[n−k], is the quadrature signal (Q) associated with the input sinusoid x(t). Accordingly, if the input of the Hilbert transformer x[n]=a[n]cos φ[n], then the output y[m]=a[m]sin φ[m], where m=n−k and k=T_{D}/T, which is an integer equal to the ratio of the signal delay to the sample period.

The filtered, digitized sinusoid x[n] is also passed to delay device 18 where it is delayed, step 36, resulting in the signal. x[n−k], which is the in-phase signal (I) associated with the input sinusoid x[n]. The amount of the delay introduced by the delay device 18 is the same as the delay which results from the approximation produced in transformer 24. Accordingly, there is no timing delay between the in-phase I and quadrature Q signals.

Therefore, after being processed by the delay device 18 and the transformer 24, the original input sinusoid x(t)=a(t)cos φ(t) has been transformed to the in-phase signal I=x[m]=a[m]cos φ[m] and the quadrature signal Q=y[m]=a[m]sin φ[m], respectively.

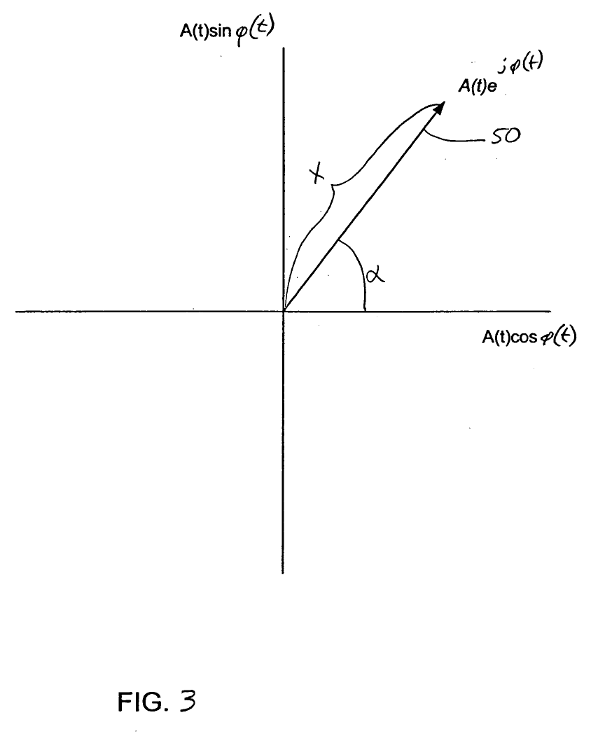

The in-phase (I) and quadrature (Q) digital signals define a rotating digital vector, such as that shown in FIG. 3. As shown in FIG. 3, the magnitude X of the vector is equal to the amplitude of the digital sinusoid x[n] and the angle a of the vector is equal to the generalized phase of the digital sinusoid x[n]. This digital vector can be expressed by the equation:

c[m]=x[m]+jy[m]=a[m]e^{jφ[m]} Eq. (4)

Once the in-phase (I) and quadrature (Q) signals are produced, the amplitude a[m] and phase φ[m] of the sinusoid x[m] can then be determined according to the following equations:

$$\begin{matrix}a [ m ] = \sqrt{{x}^{2} [ m ] + {y}^{2} [ m ]} & Eq . ( 5 ) \\ ϕ [ m ] = {tan}^{- 1} [ \frac{y [ m ]}{x [ m ]} ] & Eq . ( 6 )\end{matrix}$$

Referring back to FIGS. 1 and 2, phase processor 20 performs the operation in Eq. 6 on the in-phase (I) and quadrature (Q) signals to obtain the instantaneous phase φ, step 40, and amplitude processor 26 performs the operation in Eq. 5 on the in-phase (I) and quadrature (Q) signals to obtain the instantaneous amplitude a, step 42. While there is a delay phase associated with the computations of the amplitude and phase, this delay phase is inconsequential in terms of velocity estimation, as it represents a constant time delay and does not affect the information content. In the case of the accelerometer, the delay needs accounting for only in terms of its effect on the response characteristics of an amplitude servo if one is used to control the amplitude, i.e., for servo stability.

Processor 19, including phase processor 20 and amplitude processor 26 preferably includes a Coordinate Rotation Digital Computer (CORDIC) for fast digital trigonometric computations as described in the article “The Cordic Trigonometric Computing Technique”, published in “IRE Transactions on Electronic Computers”, September 1959 by J. E. Volder. The computations are effected via simple signal processing operations such as binary shifts, additions, subtractions and calling prestored constants. The CORDIC-thus has a very simple and compact integrable circuit structure which in an integrated form requires a comparatively low gate count. However, while, in the preferred embodiment, the CORDIC conversion process is used in separating phase attributes of complex samples from magnitude attributes, those skilled in the art can adapt other techniques, such as table look-ups and the like, in particular applications.

Accordingly, the present invention provides a method of and system for determining the instantaneous amplitude and phase of the sinusoidal output from a vibratory accelerometer or other sensor. The system first digitizes the sinusoid and then passes the digitized sinusoid through a filter in order to attenuate out-of-band noise such as harmonics and other spurious artifacts in the signal. The digitized sinusoid is then delayed to produce the in-phase signal associated with the sinusoid. A transformer is used to introduce a phase shift and an identical delay to the sinusoid in order to produce the quadrature signal associated with the sinusoid. The in-phase and quadrature signals are then processed, preferably using the CORDIC algorithm, to determine the instantaneous amplitude and phase of the sinusoid. The system is a software-based system, therefore minimizing the need for hardware, does not require a tracking reference oscillator, a phase-lock loop or analog interpolation, and thus produces more accurate measurements than the prior art due to the decrease in the sensitivity of the system to noise and other environmental factors.

The invention may be embodied in other specific forms without departing from the spirit or essential characteristics thereof. For example, while the invention has been described in connection with a vibratory accelerometer, it will be understood that the invention may be used to determine the instantaneous amplitude and phase of the output of any sensor which generates a nearly sinusoidal output. Such sensors include, but are not limited to, gyroscopes, microphones, hydrophones, vibration sensors and MEMS chemical sensors. The present embodiments are therefore to be considered in respects as illustrative and not restrictive, the scope of the invention being indicated by the appended claims rather than by the foregoing description, and all changes which come within the meaning and range of the equivalency of the claims are therefore intended to be embraced therein.

1. A method of determining the instantaneous amplitude (a) and phase (φ) of a sinusoid comprising:
A. digitizing said sinusoid to form a first signal which is the in-phase component (I) of said sinusoid;
B. introducing a phase shift into said digitized sinusoid to produce the quadrature component (Q) of said sinusoid;
C. processing said in-phase and quadrature components to compute the instantaneous phase (φ) of said sinusoid; and
D. processing said in-phase and quadrature components to compute the instantaneous amplitude (a) of said sinusoid:

2. The method of claim 1 further comprising filtering said sinusoid before step B.

3. The method of claim 1 wherein step B further includes introducing a predetermined delay into said quadrature component (Q).

4. The method of claim 3 further comprising introducing said predetermined delay into said in-phase component (I) before step C.

5. The method of claim 4 wherein step C comprises processing the in-phase and quadrature signals according to the following equation:
φ=tan⁻¹(Q/I).

6. The method of claim 1 wherein step C comprises processing the in-phase and quadrature signals according to the following equation:
φ=tan⁻¹(Q/I).

7. The method of claim 1 wherein step D comprises processing the in-phase and quadrature signals according to the following equation:
a=\sqrt{(Q²+I²)}.

8. The method of claim 4 wherein step D comprises processing the in-phase and quadrature signals according to the following equation:
a=\sqrt{(Q²+I²)}.

9. The method of claim 2 wherein said filtering step comprises attenuating out-of-band noise in said sinusoid.

10. The method of claim 8 wherein said sinusoid is an output of a vibratory sensor.

11. The method of claim 10 wherein said vibratory sensor is an accelerometer.

12. A system for determining the instantaneous phase and amplitude of an analog sinusoid comprising:
a sensor which produces said analog sinusoid output in response to the measurement of a parameter;
an analog-to-digital converter which receives said analog sinusoid from the sensor and converts said analog sinusoid to a digital sinusoid which represents the in-phase component (I) of said sinusoid;
a phase shift device which receives said digital sinusoid and produces the quadrature component (Q) of said digital sinusoid by introducing a phase shift to said digital sinusoid;
an amplitude computation device which receives said in-phase (I) and quadrature (Q) components and computes the instantaneous amplitude (a) of said digital sinusoid; and
a phase computation device which receives said in-phase (I) and quadrature (Q) components and computes the instantaneous phase (φ) of said digital sinusoid.

13. The system of claim 12 further comprising a filter device which receives said digital sinusoid from said analog-to-digital converter and removes out-of-band noise in said digital sinusoid before passing said digital sinusoid to said phase shift device.

14. The system of claim 13 wherein said phase shift device produces said quadrature signal (Q) by introducing a −90 degree phase shift into said digital sinusoid.

15. The system of claim 14 wherein said phase shift device further introduces a predetermined delay into said quadrature component (Q).

16. The system of claim 15 further comprising a delay device which introduces said predetermined delay into said in-phase component (I).

17. The system of claim 15 wherein said phase shift device comprises a Hilbert transformer approximation device.

18. The system of claim 16 wherein said amplitude computation device computes the instantaneous amplitude (a) of said digital sinusoid by processing said in-phase (I) and quadrature (Q) signals according to the equation φ=\sqrt{(Q²+I²)}.

19. The system of claim 18 wherein said phase computation device computes the instantaneous phase (φ) of said digital sinusoid by processing said in-phase (I) and quadrature (Q) signals according to the equation φ=tan⁻¹(Q/I).

20. The system of claim 12 wherein said amplitude computation device computes the instantaneous amplitude (a) of said digital sinusoid by processing said in-phase (I) and quadrature (Q) signals according to the CORDIC algorithm.

21. The system of claim 16 wherein said phase computation device computes the instantaneous phase (φ) of said digital sinusoid by processing said in-phase (I) and quadrature (Q) signals according to the CORDIC algorithm.

22. The system of claim 16 wherein said sensor comprises a vibratory accelerometer.

23. The system of claim 16 wherein said sensor comprises one of an accelerometer, a gyroscope, a microphone, a vibration sensor and a chemical sensor.

24. A system for determining the instantaneous amplitude (a) and phase (φ) of an analog sinusoid comprising:
a sensor which produces said analog sinusoid output in response to the measurement of a parameter;
an analog-to-digital converter which receives said analog sinusoid from the sensor and converts said analog sinusoid to a digital sinusoid to form the in-phase component (I) of said sinusoid;
a Hilbert transformer approximation device which receives said digital sinusoid and produces the quadrature component (Q) of said digital sinusoid by introducing a phase shift to said digital sinusoid;
an amplitude computation device which receives said in-phase (I) and quadrature (Q) components and computes the instantaneous amplitude (a) of said digital sinusoid by processing said in-phase (I) and quadrature (Q) components according to the equation a=\sqrt{(Q²+I²)}; and
a phase computation device which receives said in-phase (I) and quadrature (Q) components and computes the instantaneous phase (φ) of said digital sinusoid by processing said in-phase (I) and quadrature (Q) components according to the equation φ=tan⁻¹(Q/I).

25. The system of claim 24 wherein said Hilbert transformer approximation device further introduces a predetermined delay into said quadrature component (Q).

26. The system of claim 25 further comprising a delay device which introduces said predetermined delay into said in-phase component (I).

27. A system for determining the instantaneous amplitude and phase of an analog sinusoid comprising:
a sensor which produces said analog sinusoid output in response to the measurement of a parameter;
an analog-to-digital converter which receives said analog sinusoid from the sensor and converts said analog sinusoid to a digital sinusoid sinusoid to form the in-phase component (I) of said sinusoid;
a Hilbert transformer approximation device which receives said digital sinusoid and produces the quadrature component (Q) of said digital sinusoid by introducing a phase shift to said digital sinusoid;
an amplitude computation device which receives said in-phase (I) and quadrature (Q) components and computes the instantaneous amplitude (a) of said digital -sinusoid by processing said in-phase (I) and quadrature (Q) components according to the CORDIC algorithm; and
a phase computation device which receives said in-phase (I) and quadrature (Q) components and computes the instantaneous phase (φ) of said digital sinusoid by processing said in-phase (I) and quadrature (Q) components according to the CORDIC algorithm.

28. The system of claim 27 wherein said Hilbert transformer approximation device further introduces a predetermined delay into said quadrature component (Q).

29. The system of claim 28 further comprising a delay device which introduces said predetermined delay into said in-phase component (I).

30. The system of claim 29 wherein said sensor comprises one of an accelerometer, a gyroscope, a microphone, a vibration sensor and a chemical sensor.

31. A method of determining the amplitude (a) and phase ((p) of a sinusoid comprising:
A. measuring a parameter with a sensor;
B. generating an analog sinusoid representative of said parameter;
C. digitizing said analog sinusoid to produce a digital sinusoid;
D. filtering said digital sinusoid to attenuate out-of-band noise in said digital sinusoid;
E. producing an in-phase signal (I) associated with said digital sinusoid;
F. introducing a phase shift into said digital sinusoid to produce a quadrature signal (Q) associated with said digital sinusoid;
G. processing said in-phase (I) and quadrature (Q) signals to compute said amplitude (a) of said digital sinusoid by applying the equation a=\sqrt{(Q²+I²)}; and
H. processing said in-phase (I) and quadrature (Q) signals to compute said phase (φ) of said digital sinusoid by applying the equation φ=tan⁻¹(Q/I).

32. The method of claim 31 wherein step F includes introducing a predetermined delay into said digital sinusoid.

33. The method of claim 32 further comprising introducing said predetermined delay into said in-phase signal (I) prior to step G.

34. The method of claim 32 wherein, in step F, said phase shift is equal to −90 degrees.

35. The method of claim 34 wherein said sensor comprises one of an accelerometer, a gyroscope, a microphone, a vibration sensor and a chemical sensor.

36. A method of determining the amplitude (a) and phase (p) of a sinusoid comprising:
A. measuring a parameter of an object with a sensor;
B. generating an analog sinusoid representative of said parameter;
C. digitizing said analog sinusoid to produce a digital sinusoid;
D. filtering said digital sinusoid to attenuate out-of-band noise in said digital sinusoid;
E. introducing a delay into said digital sinusoid to produce an in-phase signal (I) associated with said digital sinusoid;
F. performing a Hilbert transform approximation of said digital sinusoid to introduce a phase shift plus delay into said digital sinusoid, thereby producing a quadrature signal (Q) associated with said digital sinusoid;
G. processing said in-phase (I) and quadrature (Q) signals to compute said amplitude (a) of said digital sinusoid by applying the equation a=\sqrt{(Q²+I²)}; and
H. processing said in-phase (I) and quadrature (Q) signals to compute said phase (φ) of said digital sinusoid by applying the equation φ=tan⁻¹(Q/I).

37. The method of claim 36 wherein said sensor comprises one of an accelerometer, a gyroscope, a microphone, a vibration sensor and a chemical sensor.

38. A method of determining the amplitude (a) and phase (φ) of a sinusoid comprising:
A. measuring a parameter of an object with a sensor;
B. generating an analog sinusoid representative of said parameter;
C. digitizing said analog sinusoid to produce a digital sinusoid;
D. filtering said digital sinusoid to attenuate out-of-band noise in said digital sinusoid;
E. producing an in-phase signal (I) associated with said digital sinusoid; F. introducing a phase shift into said digital sinusoid, thereby producing a quadrature signal (Q) associated with said digital sinusoid;
G. processing said in-phase (I) and quadrature (Q) signals to compute said amplitude (a) of said digital sinusoid according to the CORDIC algorithm; and
H. processing said in-phase (I) and quadrature (Q) signals to compute said phase (φ) of said digital sinusoid according to the CORDIC algorithm.

39. The method of claim 38 wherein step F includes introducing a predetermined delay into said digital sinusoid.

40. The method of claim 29 further comprising introducing said predetermined delay into said in-phase signal prior to step G.
